(19) United States
(12) Patent Application Publication
(10) Pub. No.: US 2015/0028912 A1
(43) Pub. Date: Jan. 29, 2015

(54) BOARD FOR PROBE CARD, METHOD OF MANUFACTURING THE SAME, AND PROBE CARD

(71) Applicant: SAMSUNG ELECTRO-MECHANICS CO., LTD., Suwon (KR)

(72) Inventors: Beom Joon CHO, Suwon (KR); Jung Goo CHOI, Suwon (KR); Ji Sung NA, Suwon (KR); Yun Hwi PARK, Suwon (KR); Kwang Jae OH, Suwon (KR); Ho Sung CHOO, Suwon (KR); Ji Hwan SHIN, Suwon (KR)

(21) Appl. No.: 14/322,660

(22) Filed: Jul. 2, 2014

(30) Foreign Application Priority Data
Jul. 26, 2013 (KR) 10-2013-0088976
Mar. 10, 2014 (KR) 10-2014-0027688

(51) Int. Cl. G01R 1/04; H05K 13/00

(52) U.S. Cl. CPC G01R 1/04; H05K 13/00
USPC 324/756.07; 29/830

(57) ABSTRACT

A board for a probe card includes a ceramic board including a first insulating layer, and second insulating layers disposed on one surface of the first insulating layer and including cavities for receiving electronic components, conductive patterns disposed on the first and second insulating layers, conductive vias electrically connecting the conductive patterns, and a capacitor disposed in the cavities. The cavities have a depth greater than a thickness of the capacitor to secure a space in a lower portion of the cavity after receiving the capacitor.

### CROSS-REFERENCE TO RELATED APPLICATION

This application claims priority to, and of Korean Patent Application Nos. 10-2013-0088976 filed on Jul. 26, 2013, and 10-2014-0027688 filed on Mar. 10, 2014, with the Korean Intellectual Property Office, the entire contents of which are hereby incorporated by reference.

### TECHNICAL FIELD

The present inventive concept generally relates to a board for a probe card having a capacitor embedded therein, a method of manufacturing the same, and a probe card.

### BACKGROUND

Unless otherwise indicated herein, the materials described in this section are not prior art to the claims herein and are not admitted to be prior art by inclusion in this section. A semiconductor device is manufactured through a fabrication process and an assembly process. The fabrication process includes forming a circuit pattern and a contact pad for inspection on a wafer. The assembly process includes assembling the wafer including the circuit pattern and the contact pad formed thereon as an individual chip.

An electrical die sorting (EDS) process is performed between the fabrication process and the assembly process described above. In the EDS process, electric signals are applied to contact pads formed on wafers to inspect electrical properties of the wafers, and the semiconductor devices are sorted into good products and defective products by such an EDS process.

Inspection apparatuses have mainly been used in electrical property inspections conducted on the semiconductor devices. Such inspection apparatuses include testers for the generation of inspection signals and the determination of inspection results, performance boards, probe stations for loading and unloading semiconductor wafers, chucks, probers, probe cards, and the like.

Probe cards, electrically connecting semiconductor wafers and testers together, may serve to receive signals generated in the testers via the performance boards. The probe cards, further, transfer the signals to chip pads in the wafers, and transfer signals outputted from the chip pads to the testers through the performance boards.

The probe cards may be configured of boards formed by stacking a plurality of ceramic green sheets including circuit patterns, electrode pads, via electrodes and the like, to manufacture multilayer bodies, and sintering the multilayer bodies. The boards subsequently are coupled to probe pins.

As semiconductor devices have been continuously miniaturized due to the development of integration technologies in the area of semiconductor circuits and as circuit patterns formed on wafers by the fabrication process and contact pads connected to the circuit patterns have been highly integrated, inspection apparatuses for semiconductor devices need to be extremely precise.

Inboards for a highly integrated probe card for inspection of a highly integrated wafer, a power noise problem has been generated to an excessive degree due to an increase in a level of a current required to evaluate an operation, and it may be difficult to solve the power noise problem in current ceramic board structures in which decoupling capacitors are mounted in outer regions of board surfaces spaced apart from test pin regions.

In order to solve this problem, a need exists for improving a structure of boards for a probe card to decrease the generated noise.

### SUMMARY

Some embodiments of the present inventive concept may provide a board for a probe card, embedded with a capacitor, having excellent durability and noise decreasing effects, a method of manufacturing the same, and a probe card.

An aspect of the present disclosure relates to a board for a probe card including a ceramic board, conductive patterns, conductive vias, and a capacitor. The ceramic board includes a first insulating layer, and second insulating layers disposed on a first surface of the first insulating layer and including cavities for receiving electronic components. The conductive patterns are printed on the first and second insulating layers.

The conductive vias electrically connect the conductive patterns. The capacitor is disposed in the cavities. The cavities have a depth greater than a thickness of the capacitor to secure a predetermined space in a lower portion of the cavities after receiving the capacitor.

The conductive pattern may include a pattern disposed on a second surface of the first insulating layer opposing to the first surface of the first insulating layer. The pattern may be connected to a test pin.

An upper portion of the cavities may be in contact with the first insulating layer, and the capacitor may be disposed in the upper portion of the cavities.

A thickness of the first insulating layer may be in a range of 0.05 mm to 1.2 mm.

A thickness of the ceramic board may be 2.0 mm or greater.

The capacitor may contain a high degree of permittivity ceramic capable of being sintered at 1000 to 1400° C.

The ceramic board may contain alumina (Al₂O₃) and glass at a content of 100 to 233 parts by weight of the glass based on 100 parts by weight of the alumina.

Bending strength of the ceramic board may be from 150 MPa to 350 MPa.

Another aspect of the present disclosure encompasses a method of manufacturing a board for a probe card. According to the method, a capacitor including a dielectric layer is manufactured. A plurality of green sheets are prepared. Conductive patterns, conductive vias, and a receiving part are prepared for embedding the capacitor, in the green sheet. The green sheets are stacked to embed the capacitor in the receiving part to thereby form a green sheet multilayer body. The green sheet multilayer body is sintered to form a ceramic board, the ceramic board including a first insulating layer and second insulating layers disposed on one surface of the first insulating layer, the second insulating layers including a cavity for receiving the capacitor. The cavity may have a depth greater than a thickness of the capacitor to secure a predetermined space in a lower portion of the cavity after receiving the capacitor.

A thickness of the first insulating layer may be in a range of 0.05 mm to 1.2 mm.

A thickness of the ceramic board may be 2.0 mm or greater.

A sintering temperature of the dielectric layer may be higher than a sintering temperature of the multilayer body.

The ceramic board may contain alumina (Al₂O₃) and glass at a content of 100 to 233 parts by weight of the glass based on 100 parts by weight of the alumina.

Still another aspect of the present disclosure relates to a probe card including a ceramic board, conductive patterns, conductive vias, a capacitor and a test pin. The ceramic board includes a first insulating layer and second insulating layers disposed on a first surface of the first insulating layer and including a cavity for receiving an electronic component. The conductive patterns are disposed in the ceramic board and include a connection pattern disposed on a second surface of the first insulating layer. The conductive vias electrically connect the conductive patterns. The capacitor is disposed in the cavity. The test pin is connected to the connection pattern. A thickness of the first insulating layer may be in a range of 0.05 or greater, but 1.2 mm or smaller.

Still another aspect of the present disclosure encompasses a board for a probe card including a ceramic board, conductive patterns, conductive vias, and a capacitor. The ceramic board includes a first insulating layer, and second insulating layers disposed on a first surface of the first insulating layer. The second insulating layers have a cavity exposing a surface of the first insulating layer. The conductive patterns are disposed on the first and second insulating layers. The conductive vias electrically connect the conductive patterns. The capacitor is disposed on the exposed surface of the first insulating layer. The cavity has a depth greater than a thickness of the capacitor.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a cross-sectional view schematically illustrating a board for a probe card according to an exemplary embodiment of the present inventive concept.

FIG. 2 is a flow chart for describing a method of manufacturing a board for a probe card according to an exemplary embodiment of the present inventive concept.

FIGS. 3A through 3E are cross-sectional views illustrating the respective processes of the method of manufacturing a board for a probe card according to an exemplary embodiment of the present inventive concept.

FIG. 4 is a cross-sectional view schematically illustrating a probe card according to an exemplary embodiment of the present inventive concept.

### DETAILED DESCRIPTION

Hereinafter, embodiments of the present inventive concept will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

Board 200 for Probe Card

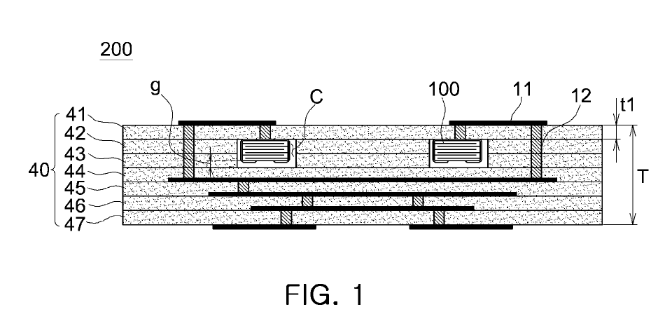

FIG. 1 is a cross-sectional view schematically illustrating a board 200 for a probe card having a capacitor embedded therein according to an exemplary embodiment of the present inventive concept.

The board 200 for a probe card having a capacitor embedded therein according to an exemplary embodiment of the present inventive concept may include a ceramic board 40, conductive patterns 11, conductive vias 12, and a capacitor 100. The ceramic board 40 may include a first insulating layer 41 and second insulating layers 42 and 43 disposed on one surface of the first insulating layer 41 and have a cavity C formed therein so as to receive an electronic component therein. The conductive patterns 11 may be formed in the ceramic board. The conductive vias 12 may electrically connect the conductive patterns. The capacitor 100 may be disposed in the cavity.

The conductive pattern 11 may include a first pattern (connection pattern) formed on the other surface of the first insulating layer 41 and connected to a test pin and a second pattern disposed in the ceramic board.

The ceramic board may be formed by stacking a plurality of insulating layers 41 to 47. Insulating layers having the cavity formed therein may be defined as the second insulating layers 42 and 43. The insulating layer 41 formed on the second insulating layer to thereby be disposed adjacently to the test pin may be defined as the first insulating layer 41.

The ceramic board may include additional insulating layers 44 to 47 having a signal layer, a ground layer or the like embedded therein, in addition to the first and second insulating layers.

The ceramic board 40 may contain low temperature co-fired ceramics (LTCC) capable of being sintered at a relatively low temperature. In detail, the ceramic board according to an embodiment of the present inventive concept may contain LTCC capable of being sintered at a temperature of 900° C. or less.

According to an exemplary embodiment of the present inventive concept, the LTCC may contain alumina (Al₂O₃) and glass. 100 to 233 parts by weight of the glass may be contained in the LTCC based on 100 parts by weight of alumina.

The glass may be M-Al—Si—O (M is Ca, Sr, or Ba) based crystallized glass or Si—B—R—O (R is Li, Na, K, or the like, as an alkali metal) based borosilicate glass.

The LTCC according to an exemplary embodiment of the present inventive concept may contain glass containing 25 to 40 wt % of M element (M is Ca, Sr, or Ba), 30 to 45 wt % of aluminum (Al), 5 to 20 wt % of silicon (Si), and 0.1 to 5 wt % of other added elements (Zn, B, Mg, or the like), but the present inventive concept is not limited thereto.

The LTCC may be sintered at a temperature of 900° C. or less due to a low melting point of glass. For example, the LTCC may be sintered at 870° C.

Further, bending strength of the LTCC may be from 150 MPa to 350 MPa, but the present inventive concept is not limited thereto.

The capacitor 100 may contain a high degree of permittivity dielectric layer 111.

In addition, the capacitor may be a multilayer ceramic capacitor including a body 110 including a plurality of dielectric layers 111, internal electrodes 121 and 122 disposed within the body 110, and external electrodes 131 and 132 electrically connected to the internal electrodes 121 and 122.

The dielectric layers 111 may contain high permittivity ceramics capable of being sintered at 1000 to 1400° C.

For example, according to an embodiment of the present inventive concept, the ceramic board may be formed using the LTCC capable of being sintered at a temperature of 900° C. or less, such that the board may be sintered in a state in which the capacitor is embedded therein, thereby forming a board for a probe card.

Unlike a ceramic board containing HTCC or mullite, the ceramic board 40 according to an embodiment of the present inventive concept may contain the LTCC, such that the capacitor 100 disposed in the cavity C may not be affected during a sintering process of a multilayer body. For example, since a sintering temperature of the multilayer body is lower than that of the dielectric layer included in the capacitor, even when the multilayer body is sintered in a state in which the capacitor sintering in advance is disposed therein (in the cavity), the capacitor may not be damaged.

The first insulating layer 41 may contact the second insulating layers 42 and 43, and the cavity C may have a depth equal to a total thickness of the second insulating layers 42 and 43. For example, since the thickness of the second insulating layers 42 and 43 is the same as the depth of the cavity C, the first insulating layer 41 may be formed to contact, e.g., be exposed to, the cavity.

Although the first insulating layer is represented as a single layer in FIG. 1, the first insulating layer may be formed by stacking one or more insulating layers in consideration of a thickness thereof.

In the cavity C, a portion contacting, e.g., exposing, the first insulating layer 41 may be defined as an upper portion of the cavity, and a portion opposite thereto may be defined as a lower portion of the cavity.

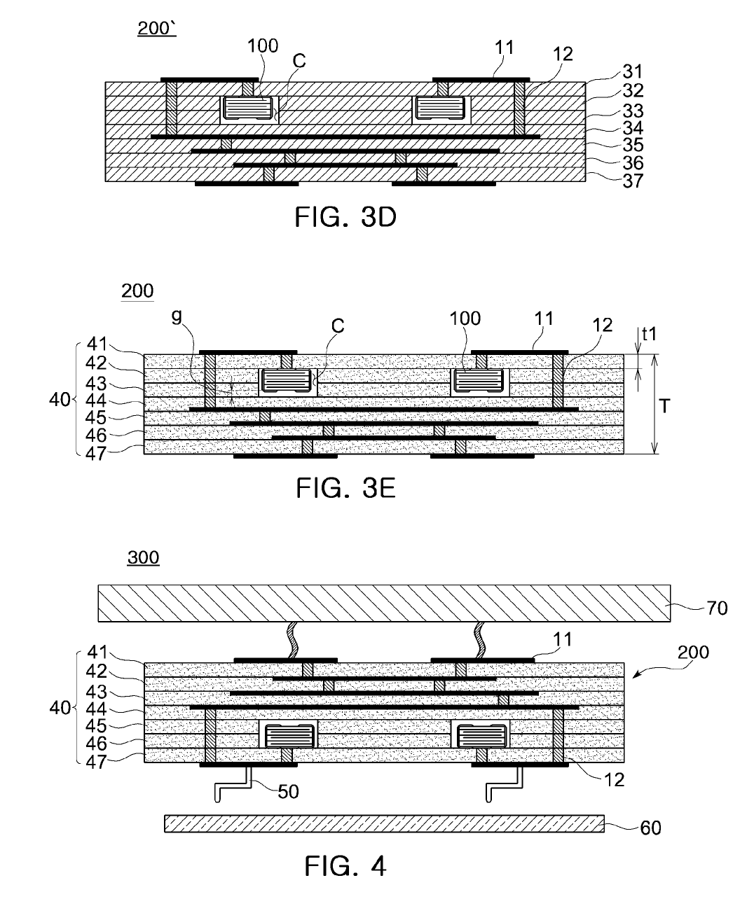

The capacitor 100 may be mounted in the upper portion of the cavity C. In other words, the capacitor 100 may be mounted on one surface of the first insulating layer 41. When the capacitor 100 is mounted in the upper portion of the cavity C instead of the lower portion thereof, the capacitor may be disposed to be closer to the test pin 50 (see FIG. 4), such that a physical distance between the capacitor and the test pin may be decreased, thereby further decreasing power noise to be generated by parasitic inductance.

In addition, with reference to FIG. 1, the cavity C may have a depth greater than a thickness of the capacitor 100, such that a predetermined space (gap) g may be secured in the lower portion of the cavity after the capacitor is received in the cavity.

For example, the cavity C may secure the predetermined space (gap) g even when the capacitor is received therein.

If the predetermined space (gap) is not secured after the capacitor 100 is received in the cavity C, the embedded capacitor may contact an inner wall or surface of the cavity (e.g., a surface of a green sheet forming the ceramic board) to thereby react with the green sheet during a sintering process of a green sheet multilayer body. In this case, a shape of the cavity may be deformed or the capacitor may be damaged due to differences of shrinkage rates and coefficients of thermal expansion between the capacitor and the green sheet.

Further, when the board is used as the board for a probe card after sintering, if warpage of the board is generated due to the load transferred from the test pin but the gap is not secured, the embedded capacitor may be damaged.

A thickness t1 of the first insulating layer 41 may be a distance from one surface of the first insulating layer 41 which faces the cavity C to the other surface of the first insulating layer on which the first pattern (connection pattern) for connection to the test pin 50 (see FIG. 4) is disposed.

For example, the thickness t1 of the first insulating layer 41 may be a distance from a surface facing the cavity C to one surface of the ceramic board 40 on which the first pattern for connection to the test pin is disposed.

The board for a probe card embedded with a capacitor is the board for a probe card having a capacitor embedded therein, according to an embodiment of the present inventive concept. A board for a probe card for testing defects of an electronic component or a semiconductor wafer, may be embedded with the capacitor.

In detail, according to an embodiment of the present inventive concept, the board for a probe card capable of decreasing impedance and having excellent durability may be provided by controlling a distance from one surface of the first insulating layer 41 facing the cavity C to one surface of the ceramic board 40 on which the conductive pattern for connection to the test pin is disposed, for example, the thickness t1 of the first insulating layer 41.

In further detail, the thickness t1 of the first insulating layer 41 may be from 0.05 to 1.2 mm. When the thickness t1 of the first insulating layer 41 is less than 0.05 mm, the first insulating layer 41 may not endure a load transferred through the test pin 50 during a testing process of a defect of an electronic component or a semiconductor wafer using the board for a probe card according to an embodiment of the present inventive concept to thereby be broken. When the thickness of the first insulating layer 41 is more than 1.2 mm, noise impedance may be increased due to a distance between a surface which the capacitor C faces and the test pin.

Further, when a diameter of the conductive via 12 is significantly increased, the thickness of the first insulating layer 41 may be increased. However, considering that an upper limit of a diameter of the conductive via 12 for maintaining a degree of integration of the board to be constant is 100 μm, when a distance between a surface which the capacitor faces and one surface of the ceramic board 40 on which the conductive pattern for connection to the test pin is disposed is more than 1.2 mm, noise impedance may be increased, such that the noise impedance may be more than 20 mΩ, an allowable upper limit.

Therefore, the thickness t1 of the first insulating layer may be from 0.05 to 1.2 mm.

Further, the ceramic board 40 may have a thickness T of 2.0 mm or more in order to be used as a board for a probe card. The ceramic board may include the signal layer, the ground layer, a power layer or the like embedded therein, in order to implement electric properties as the board for a probe card. In order to endure pressure applied to the board at the time of assembling the probe card and testing a wafer, the entire thickness of the ceramic board may be 2.0 mm or more.

In an embodiment of the present inventive concept, even in the case of using a ferroelectric material having a permittivity higher than 1000 as a high degree of permittivity material configuring the dielectric layer of the capacitor, the board for a probe card having a capacitor embedded therein may not damage the capacitor during the sintering process of the ceramic board but have excellent durability and noise decreasing effect.

Method of Manufacturing Board for Probe Card

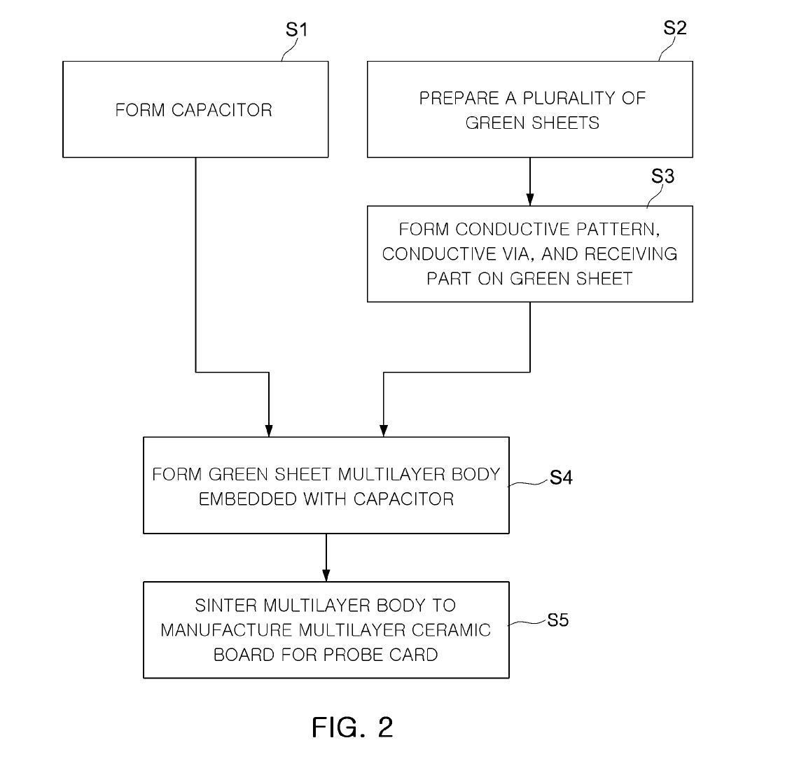

FIG. 2 is a flow chart for describing a method of manufacturing a board for a probe card according to an exemplary embodiment of the present inventive concept.

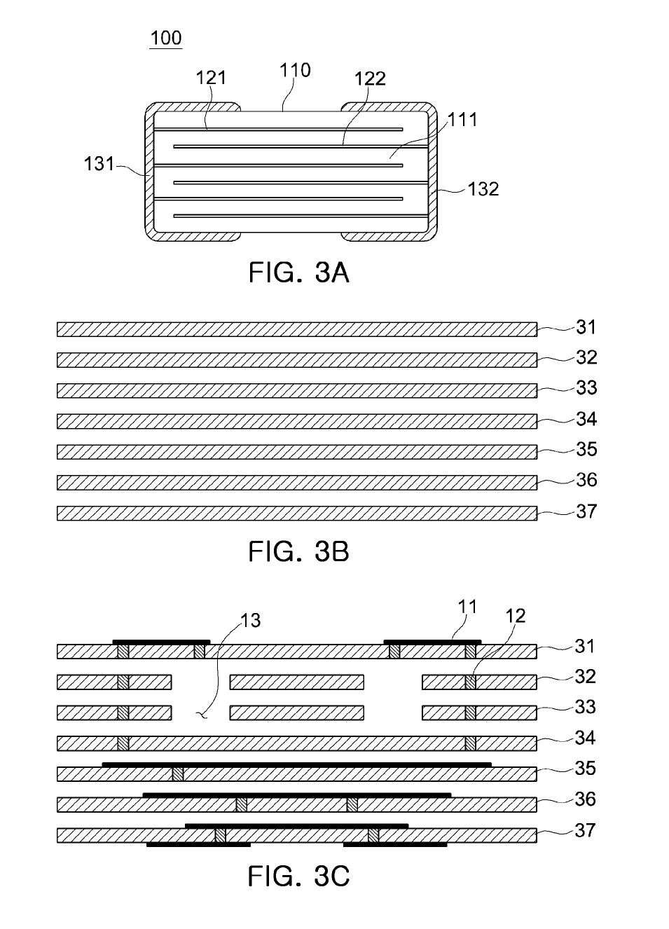

FIGS. 3A through 3E are cross-sectional views illustrating each of the processes of the method of manufacturing a board for a probe card embedded with a capacitor according to an exemplary embodiment of the present inventive concept.

Referring to FIGS. 2 through 3E, the method of manufacturing a board for a probe card embedded with a capacitor according to an exemplary embodiment of the present inventive concept may include manufacturing a capacitor including a dielectric layer (S1). A plurality of green sheets may be prepared (S2). Conductive patterns, conductive vias, and a receiving part may be formed for embedding the capacitor in the green sheet (S3). The green sheets may be stacked so that the capacitor is embedded therein to form a green sheet multilayer body (S4). The multilayer body may be sintered to form a ceramic board including a first insulating layer and second insulation layers formed on one surface of the first insulating layer and including a cavity to accommodate the capacitor received in the cavity (S5).

The cavity may have a depth greater than a thickness of the capacitor, such that a predetermined space may be secured in a lower portion of the cavity after receiving the capacitor therein.

When a thickness of the first insulating layer is defined as t1, t1 may be in a range of from 0.05 to 1.2 mm (0.05 mm t1 ≦1.2 mm).

When a thickness of the ceramic board is defined as T, T may be 2.0 or more (T 2.0 mm).

The dielectric layer may contain a high degree of permittivity ceramic capable of being sintered at 1000 to 1400° C., and the ceramic board may contain LTCC having a sintering temperature lower than that of the dielectric layer.

Hereinafter, the method of manufacturing a board for a probe card having a capacitor embedded therein according to an exemplary embodiment of the present inventive concept will be described in detail. However, descriptions overlapping with those of the above-mentioned board for a probe card embedded with a capacitor will be omitted, and a difference will be mainly described.

Hereinafter, the present disclosure will be described in detail with reference to the accompanying drawings.

FIG. 2 is a flow chart for describing a method of manufacturing a board for a probe card embedded with a capacitor according to an exemplary embodiment of the present inventive concept.

In the method of manufacturing a board for a probe card having a capacitor embedded therein according to an exemplary embodiment of the present inventive concept, a process of manufacturing the capacitor may be performed before the sintering process of the multilayer body forming the ceramic board.

Firstly, before stacking a plurality of green sheets 31-37 (see FIG. 3B), as shown in FIG. 3A, a capacitor 100 including a dielectric layer 111 may be formed using a ceramic sheet having a high degree of permittivity (S1). The capacitor 100 may be variously implemented according to the required structure of the capacitor. For example, the capacitor 100 may be a multilayer ceramic capacitor including a plurality of ceramic sheets, first and second internal electrodes 121 and 122 disposed to face each other, having the ceramic sheet therebetween, and first and second external electrodes 131 and 132 electrically connected to the first and second internal electrodes 121 and 122.

Alternatively, the capacitor may be a capacitor having a single layer structure in which a single high permittivity ceramic sheet and first and second electrodes disposed on portions of upper and lower surfaces of the ceramic sheets configure a capacitor region. In addition, the capacitor, for example, a capacitor part, may be a single capacitor or an array type capacitor in which a plurality of capacitors are arranged. The high permittivity material configuring the ceramic sheet of the capacitor may be a ferroelectric material having a permittivity of about 1000 or more, for example, 2000 to 3000, but the present inventive concept is not limited thereto. As a representative example of the ferroelectric material, BaTiO₃ may be used. Other materials may be used as the ferroelectric material.

In consideration of a general high permittivity material, the sintering temperature of the ceramic sheet may be in a range of from about 1000° C. to about 1400° C.

Separately from the manufacturing process of the capacitor as described above, as shown in FIG. 3B, a process of preparing the plurality of green sheets 31 to 37 may be performed (S2). The green sheets may be formed using a mixture of Al₂O₃ and a glass based component.

The ceramic board 40 may contain low temperature co-fired ceramics (LTCC) capable of being sintered at a relatively low temperature. For example, the ceramic board may contain LTCC capable of being sintered at a temperature of 900° C. or less.

According to an exemplary embodiment of the present inventive concept, the LTCC may contain alumina (Al₂O₃) and glass. 100 to 233 parts by weight of the glass may be contained in the LTCC based on 100 parts by weight of alumina.

The glass may be M-Al—Si—O (M is Ca, Sr, or Ba) based crystallized glass or Si—B—R—O (R is Li, Na, K, or the like, as an alkali metal) based borosilicate glass.

The LTCC according to an exemplary embodiment of the present inventive concept may contain glass containing 25 to 40 wt % of M element (M is Ca, Sr, or Ba), 30 to 45 wt % of aluminum (Al), 5 to 20 wt % of silicon (Si), and 0.1 to 5 wt % of other added elements (Zn, B, Mg, or the like), but the present inventive concept is not limited thereto.

The LTCC may be sintered at a temperature of 900° C. or less due to a low melting point of glass, and for example, the LTCC may be sintered at 870° C.

Then, as shown in FIG. 3C, the process of forming the conductive pattern 11 for the formation of an interlayer circuit on the prepared ceramic sheets 31 to 37, and the forming process of the conductive via 12 and the receiving part 13 therein may be performed (S3). The conductive pattern 11 may be formed by a publicly known process such as a screen printing process, and the conductive via 12 may be implemented by sequentially performing a punching process and a printing process of filling a via with the conductive material.

In FIGS. 3B and 3C, the green sheet forming the first insulating layer after sintering is represented by a reference numeral 31, and the green sheets forming the second insulating layers are represented with reference numerals 32 and 33, in which the cavity 13 for receiving an electronic component is formed.

The ceramic board may include additional insulating layers for embedding a signal layer, a ground layer, or the like embedded therein. With reference to FIG. 3B, in addition to the first and second insulating layers, and green sheets forming the additional insulating layers are represented by reference numerals 34 to 37.

A thickness of the green sheet may be appropriately set in consideration of thicknesses of the first insulating layer, which is formed after sintering, the cavity, and the ceramic board including the first insulating layer and cavity.

Next, as shown in FIG. 3D, a multilayer body 200′ may be formed by stacking the capacitor 100 manufactured in the forementioned process and the prepared green sheets 31 to 37 (S4). The green sheets having the receiving part 13 formed therein may be stacked to form the cavity C in a region corresponding to the receiving part. In this process, the capacitor 100 may be stacked or mounted in the cavity by an appropriate embedding method according to the structure thereof. In addition, in this stacking process, the external electrodes of the capacitor part may be connected to the conductive pattern or conductive via formed in the green sheets, respectively.

In detail, the external electrode of the capacitor may be disposed on one surface of the green sheet 31 forming the first insulating layer to thereby be connected to the conductive pattern or conductive via formed on the first insulating layer.

In detail, the cavity C may have a depth greater than a thickness of the capacitor 100 to thereby secure a predetermined margin space g. A dimension of this cavity C may be calculated in suitable consideration of a shrinkage degree of the green sheet for sintering at a low temperature during the sintering process, for example, a shrinkage degree of a material of the LTCC sheet, a thickness of a layer, and the like.

Then, as shown in FIG. 3E, the multilayer body 200 may be sintered at a relatively low temperature, thereby manufacturing the board 200 for a probe card having a capacitor embedded therein. (S5) This low temperature sintering process may be performed at a temperature ranging from about 900 to about 1100° C. Since the capacitor is embedded in a state in which it is sintered in advance, sintering shrinkage may not be generated in the capacitor during the low temperature simultaneous sintering process as described above. In addition, as the capacitor 100 is formed using the material sintered in advance, the capacitor 100 may serve to suppress the sintering shrinkage of the multilayer body 200, for example, the sintering shrinkage in a plane direction.

The stacked green sheets 31 to 37 may be sintered, thereby forming a ceramic board 40 including insulating layers 41 to 47 (FIG. 3E). For example, the ceramic board 40 may include the first insulating layer 41 including a first pattern 11 connected to a test pin and the second insulating layers 42 and 43 in which the cavity is formed.

Since a description of a thickness of the first insulating layer overlaps with that in the above-mentioned exemplary embodiment of the board for a probe card, embedded with a capacitor, the description thereof will be omitted.

As described above, according to an embodiment of the present inventive concept, even in the case of using a ferroelectric material having a permittivity greater than 1000 as a high permittivity material configuring the capacitor, the board for a probe card in which the capacitor is not damaged at the time of sintering the green sheet may be provided. Further, the board for a probe card in which deformation or cracking is not generated may be provided.

Probe Card 300

FIG. 4 is a cross-sectional view schematically illustrating a probe card 300 according an exemplary embodiment of the present inventive concept.

Referring to FIG. 4, the probe card 300 according to an exemplary embodiment of the present inventive concept may include a board 200 for a probe card and a test pin 50. The board 200 for a probe card may have a capacitor embedded therein, and a ceramic board 40. The ceramic board 40 may include a first insulating layer 41, second insulating layers 42 and 43, which are disposed on one surface of the first insulating layer 41 and include a cavity C formed therein to receive an electronic component in the cavity, conductive patterns 11 formed in the ceramic board and including a first pattern formed on the other surface of the first insulating layer 41, conductive vias 12 electrically connecting the conductive patterns, and a capacitor C disposed in the cavity. The test pin 50 may be connected to the first pattern.

For example, a thickness of the first insulating layer 41 may be 0.05 to 1.2 mm, and a thickness of the ceramic board may be 2.0 mm or more.

Hereinafter, since descriptions of the ceramic board, the conductive pattern, the conductive via, and the capacitor overlap with those in the above-mentioned board for a probe card embedded with a capacitor, the descriptions will be omitted.

The test pin 50 may be a probe pin for testing a wafer 60 and may be formed using a conductive material through which current flows. The test pin 50 may be manufactured by a micro thin plate technology applied to manufacturing of a semiconductor, but the present inventive concept is not limited thereto.

The probe card 300 may further include a printed circuit board 70 connected to the board 200 for a probe card, having a capacitor embedded therein.

The printed circuit board 70 may be configured of a circular plate having upper and lower surfaces and connected to a tester (not shown) for an inspection process.

A probe circuit pattern (not shown) for the inspection process may be formed on the upper surface of the printed circuit board 70. A groove (not shown) for suppressing interference between probe circuit patterns by current flowing in the probe circuit pattern adjacent to each other may be formed between the probe circuit patterns adjacent thereto. In addition, an interposer (not shown) may be mounted on the lower surface of the printed circuit board 70.

The interposer (not shown) may be positioned in a gap between the printed circuit board 70 and the board 200 for a probe card to serve to transfer an electric signal passing through the printed circuit board 70 for the inspection process to the board 200 for a probe card, having a capacitor embedded therein, according to the present disclosure.

One end of the interposer may be connected to the probe circuit pattern of the printed circuit board 70, and the other end of the interposer may contact the conductive pattern 11 formed in the board 200 for a probe card to thereby be electrically connected thereto.

The wafer 60 may be probed with the test pin (probe pin) 50 of the probe card 300 configured as described above, and a probing signal may be transferred to the printed circuit board 70 through the board 200 for a probe card, embedded with a capacitor.

### Experimental Example

The following Table 1 shows data obtained by calculating a minimum thickness of a first insulating layer included in a board for a probe card having a capacitor embedded therein according to an embodiment of the present inventive concept by varying the bending strength of a ceramic board and a load applied to the ceramic board.

In Experimental Example shown in Table 1, a cavity having a horizontal length of 1.3 mm and a vertical length of 0.8 mm was applied, and a conductive via having a diameter of 0.06 mm and a test pin having a pitch of 0.3 mm were used.

TABLE 1

| | | | Minimum |
|---|---|---|---|
| | | | Thickness of |
| | | | First |
| | Bending Strength | Load Applied to | insulating |
| | of Ceramic Board | Ceramic Board | layer |
| Sample | (MPa) | (kg) | (mm) |
| 1 | 150 | 0.11 | 0.100 |
| 2 | 300 | 0.11 | 0.072 |
| 3 | 350 | 0.11 | 0.067 |
| 4 | 600 | 0.11 | 0.051 |
| 5 | 150 | 0.43 | 0.206 |
| 6 | 300 | 0.43 | 0.145 |
| 7 | 350 | 0.43 | 0.135 |
| 8 | 600 | 0.43 | 0.103 |

The load applied to the ceramic board may be calculated as the product of a load (about 0.006 kg) applied to one pin and the number of pins present in a cavity region.

Therefore, a degree of integration of the conductive via in the first insulating layer and the test pin may be changed depending on a degree of integration of a wafer to be tested, such that the load applied to the ceramic board may also be changed. Since the mechanical strength of the first insulating layer may be changed according to a material forming the ceramic board, the minimum thickness of the first insulating layer capable of enduring the load may be changed.

Considering that the maximum bending strength of the ceramic board including the LTCC may not exceed 600 MPa, it may be appreciated that when a minimum thickness of the first insulating layer is calculated by combining the load applied to the ceramic board according to the degree of integration of the conductive via and the bending strength of the ceramic board, the minimum thickness of the first insulating layer under the condition in table 1 is 0.051 mm (sample 4 in Table 1).

The following Table 2 shows experimental results obtained by measuring whether or not the board for a probe card, having a capacitor embedded therein, is damaged according to the diameter of the conductive via and the thickness of the first insulating layer under the conditions shown in Table 1. The experiment of Table 2 was performed using a ceramic board having bending strength of 600 MPa, which is the maximum bending strength of the ceramic board including the LTCC, and a cavity having a horizontal length of 1.3 mm and a vertical length of 0.8 mm was applied thereto. Other conditions were the same as those in sample 4, which had the minimum thickness in Table 1.

TABLE 2

| | Diameter of | Thickness of First | Whether or |
|---|---|---|---|
| | Conductive via | Insulating Layer | Not Board is |
| Sample | (μm) | (mm) | Damaged |
| 9* | 60 | 0.02 | NG |
| 10* | 60 | 0.04 | NG |
| 11 | 60 | 0.05 | OK |
| 12 | 60 | 0.06 | OK |
| 13 | 60 | 0.07 | OK |
| 14 | 60 | 0.10 | OK |
| 15* | 80 | 0.02 | NG |
| 16* | 80 | 0.04 | NG |
| 17 | 80 | 0.05 | OK |
| 18 | 80 | 0.06 | OK |
| 19 | 80 | 0.07 | OK |
| 20 | 80 | 0.10 | OK |
| 21* | 100 | 0.02 | NG |
| 22* | 100 | 0.04 | NG |
| 23 | 100 | 0.05 | OK |
| 24 | 100 | 0.06 | OK |
| 25 | 100 | 0.07 | OK |
| 26 | 100 | 0.10 | OK |

*Comparative Example

In the case of increasing the diameter of the conductive via to decrease the number of test pins as compared to the samples shown in Table 1, it was anticipated that the thickness of the first insulating layer might be further thinned, but it may be appreciated from the experimental results shown in Table 2 that even when the integration degree of the conductive via is decreased, when a thickness of the first insulating layer is at least 0.05 mm, the board for a probe card, having a capacitor embedded therein, is not damaged during a process of testing a wafer. Therefore, the minimum thickness of the first insulating layer may be 0.05 mm or more.

Thereafter, the following Table 3 shows data obtained by measuring noise impedance values by varying the diameter of the conductive via and the length of the conductive via (thickness of the first insulating layer).

TABLE 3

| | | | Noise |
|---|---|---|---|
| | Diameter of | Length of Conductive | Impedance |
| Sample | Conductive Via (μm) | via (mm) | (mΩ) |
| 27 | 55 | 0.1 | 9 |
| 28 | 55 | 0.2 | 20 |
| 29* | 55 | 0.3 | 32 |
| 30* | 55 | 0.4 | 43 |
| 31* | 55 | 0.6 | 69 |
| 32* | 55 | 0.8 | 85 |
| 33* | 55 | 1.0 | 120 |
| 34* | 55 | 1.2 | 143 |
| 35* | 55 | 1.4 | 168 |
| 36 | 75 | 0.1 | 6 |
| 37 | 75 | 0.2 | 15 |
| 38 | 75 | 0.3 | 20 |
| 39* | 75 | 0.4 | 29 |
| 40* | 75 | 0.6 | 44 |
| 41* | 75 | 0.8 | 61 |
| 42* | 75 | 1.0 | 77 |
| 43* | 75 | 1.2 | 84 |
| 44* | 75 | 1.4 | 110 |
| 45 | 90 | 0.1 | 4 |
| 46 | 90 | 0.2 | 7 |
| 47 | 90 | 0.3 | 10 |
| 48 | 90 | 0.4 | 15 |
| 49* | 90 | 0.6 | 23 |
| 50* | 90 | 0.8 | 31 |
| 51* | 90 | 1.0 | 40 |
| 52* | 90 | 1.2 | 49 |
| 53* | 90 | 1.4 | 57 |
| 54 | 100 | 0.1 | 2 |
| 55 | 100 | 0.2 | 4 |
| 56 | 100 | 0.3 | 5 |
| 57 | 100 | 0.4 | 7 |
| 58 | 100 | 0.6 | 10 |
| 59 | 100 | 0.8 | 13 |
| 60 | 100 | 1.0 | 17 |
| 61 | 100 | 1.2 | 19 |
| 62* | 100 | 1.4 | 22 |
| 63 | 120 | 0.1 | 2 |
| 64 | 120 | 0.2 | 3 |
| 65 | 120 | 0.3 | 4 |
| 66 | 120 | 0.4 | 7 |
| 67 | 120 | 0.6 | 11 |
| 68 | 120 | 0.8 | 12 |
| 69 | 120 | 1.0 | 17 |
| 70 | 120 | 1.2 | 18 |
| 71* | 120 | 1.4 | 21 |

*Comparative Example

Referring to Table 3, it may be confirmed that in comparative samples 29 to 35, 39 to 44, 49 to 53, 62, and 71, noise impedance values exceed an allowable upper limit, i.e., 20 mΩ. As the diameter of the conductive via increases, the noise impedance value tends to decrease, and as the length of the conductive via increases, the noise impedance value tends to increase.

It may be appreciated through Table 3 that when the diameters of the conductive vias are 0.055 mm, 0.075 mm, 0.09 mm, 0.1 mm, and 0.12 mm, the lengths of the conductive vias at which the noise impedance value is 20 mΩ or less are 0.2 mm, 0.3 mm, 0.4 mm, 1.2 mm, and 1.2 mm, respectively.

When the diameter of the conductive via increases, the noise impedance value may decrease, but it may be appreciated that in the case in which the diameter of the conductive via exceeds 0.1 mm, even when the diameter of the conductive via increases, an influence of the decrease in impedance may be insignificant, such that the length of the conductive via may not exceed 1.2 mm. Therefore, it may be confirmed that even in the case of considering an increase in the diameter of the conductive via, only when the length of the conductive via is 1.2 mm, noise impedance may be 20 mΩ or less.

Further, it is confirmed that in the case of excessively increasing the diameter of the conductive via, the thickness of the first insulating layer increased, but since an upper limit of the diameter of the conductive via 12 is 100 μm, when a distance between an embedding position of the capacitor and one surface of the ceramic board on which the conductive pattern for connection to the test pin was disposed exceeded 1.2 mm, noise impedance was increased to thereby exceed the allowable upper limit of the noise impedance, i.e., 20 mΩ.

Since the depth of the conductive via is the same as the thickness of the first insulating layer, it may be confirmed through Table 3 that a thickness of the first insulating layer may be 1.2 mm or less.

Therefore, referring to results shown in Tables 1 to 3, it may be appreciated that the thickness of the first insulating layer may be 0.05 to 1.2 mm.

According to exemplary embodiments of the present inventive concept, the board for a probe card capable of having excellent durability and noise decreasing effect, the method of manufacturing the same, and the probe card may be provided.

While exemplary embodiments have been shown and described above, it will be apparent to those skilled in the art that modifications and variations could be made without departing from the spirit and scope of the present disclosure as defined by the appended claims.

What is claimed is:

1. A board for a probe card, comprising:
a ceramic board including a first insulating layer, and second insulating layers disposed on a first surface of the first insulating layer, the second insulating layers including cavities for receiving electronic components;
conductive patterns disposed on the first and second insulating layers;
conductive vias electrically connecting the conductive patterns; and
a capacitor disposed in the cavities,
wherein the cavities have a depth greater than a thickness of the capacitor to secure a space in a lower portion of the cavities after receiving the capacitor.

2. The board of claim 1, wherein the conductive pattern includes a pattern disposed on a second surface of the first insulating layer opposing to the first surface of the first insulating layer, the pattern being connected to a test pin.

3. The board of claim 1, wherein an upper portion of the cavities is in contact with the first insulating layer, and the capacitor is disposed in the upper portion of the cavities.

4. The board of claim 1, wherein a thickness of the first insulating layer is in a range of 0.05 mm to 1.2 mm.

5. The board of claim 1, wherein a thickness of the ceramic board is 2.0 mm or greater.

6. The board of claim 1, wherein the capacitor contains a high degree of permittivity ceramic capable of being sintered at 1000 to 1400° C.

7. The board of claim 1, wherein the ceramic board contains alumina (Al₂O₃) and glass at a content of 100 to 233 parts by weight of the glass based on 100 parts by weight of the alumina.

8. The board of claim 1, wherein bending strength of the ceramic board is from 150 MPa to 350 MPa.

9. A method of manufacturing a board for a probe card, comprising:
manufacturing a capacitor including a dielectric layer;
preparing a plurality of green sheets;
preparing conductive patterns, conductive vias, and a receiving part for embedding the capacitor, in the green sheet;
stacking the green sheets to embed the capacitor in the receiving part to thereby form a green sheet multilayer body; and
sintering the green sheet multilayer body to form a ceramic board, the ceramic board including a first insulating layer and second insulating layers disposed on one surface of the first insulating layer, the second insulating layers including a cavity for receiving the capacitor;
wherein the cavity has a depth greater than a thickness of the capacitor to secure a space in a lower portion of the cavity after receiving the capacitor.

10. The method of claim 9, wherein a thickness of the first insulating layer is in a range of 0.05 mm to 1.2 mm.

11. The method of claim 9, wherein a thickness of the ceramic board is 2.0 mm or greater.

12. The method of claim 9, wherein a sintering temperature of the dielectric layer is higher than a sintering temperature of the multilayer body.

13. The method of claim 9, wherein the ceramic board contains alumina (Al₂O₃) and glass at a content of 100 to 233 parts by weight of the glass based on 100 parts by weight of the alumina.

14. A probe card, comprising:
a ceramic board including a first insulating layer and second insulating layers disposed on a first surface of the first insulating layer, the second insulating layers including a cavity for receiving an electronic component;
conductive patterns disposed in the ceramic board and including a connection pattern disposed on a second surface of the first insulating layer;
conductive vias electrically connecting the conductive patterns;
a capacitor disposed in the cavity; and
a test pin connected to the connection pattern,
wherein a thickness of the first insulating layer is in a range of 0.05 or greater, but 1.2 mm or smaller.

15. A board for a probe card, having a capacitor embedded therein, the board comprising:
a ceramic board including a plurality of insulating layers, wherein a cavity for receiving an electronic component is defined at a portion of the plurality of insulating layers;
conductive patterns disposed in the ceramic board;
conductive vias electrically connecting the conductive patterns; and
a capacitor disposed in the cavity,
wherein a distance between the cavity and one surface of the ceramic board is in a range of 0.05 mm or greater, but 1.2 mm or smaller.

16. The board of claim 15, wherein the conductive pattern includes a first pattern disposed on the second surface of the first insulating layer opposing to the first surface of the first insulating layer, and connected to a test pin.

17. The board of claim 15, wherein a thickness of the ceramic board is 2.0 mm or greater.

18. The board of claim 15, wherein the capacitor is a multilayer ceramic capacitor including a body including a plurality of dielectric layers, internal electrodes disposed in the body, and external electrodes electrically connected to the internal electrodes.

19. The board of claim 15, wherein the ceramic board contains alumina (Al₂O₃) and glass.

20. The board of claim 15, wherein the cavity has a depth greater than a thickness of the capacitor, such that a space is secured after the capacitor is received in the cavity.

21. A board for a probe card, comprising:
a ceramic board including a first insulating layer, and second insulating layers disposed on a first surface of the first insulating layer, the second insulating layers having a cavity exposing a surface of the first insulating layer;
conductive patterns disposed on the first and second insulating layers;
conductive vias electrically connecting the conductive patterns; and
a capacitor disposed on the exposed surface of the first insulating layer,
wherein the cavity has a depth greater than a thickness of the capacitor.

22. The board of claim 21, wherein the depth of the cavity is the same as a thickness of the second insulating layers.
